(19) United States
(12) Patent Application Publication
(10) Pub. No.: US 2020/0036321 A1
(43) Pub. Date: Jan. 30, 2020

(54) MOTOR CONTROLLER AND MOTOR CONTROL METHOD

(71) Applicant: FANUC CORPORATION, Yamanashi (JP)

(72) Inventors: Yuuki MORITA, Yamanashi (JP); Tomohisa TSUTSUMI, Yamanashi (JP)

(73) Assignee: FANUC CORPORATION, Yamanashi (JP)

(21) Appl. No.: 16/515,988

(22) Filed: Jul. 18, 2019

(30) Foreign Application Priority Data
Jul. 24, 2018 (JP) 2018-138651

(51) Int. Cl. H02P 29/40; G01R 31/06; G01R 31/34

(52) U.S. Cl. CPC H02P 29/40; G01R 31/34; G01R 31/06

(57) ABSTRACT

To provide a motor controller and a motor control method allowing inspection for checking the presence or absence of specification error in motor winding to be conducted more simply, efficiently, and with high accuracy. A voltage command value as a command value for driving control of a motor and an excitation frequency are sampled. An actual current flowing in the motor being driven under control is detected. Theoretical values of a voltage command value, a current, and an excitation frequency are determined from a parameter for driving the motor and a condition at the time of driving. The theoretical values of the voltage command value, the current, and the excitation frequency are compared with the values of the voltage command value, the current, and the excitation frequency respectively at the time of the driving, and it is determined that there is winding abnormality if differences between the comparable values exceed a threshold range set in advance.

This application is based on and claims the benefit of priority from Japanese Patent Application No. 2018-138651, filed on 24 Jul. 2018, the content of which is incorporated herein by reference.

### BACKGROUND OF THE INVENTION

### Field of the Invention

The present invention relates to a motor controller and a motor control method.

### Related Art

Conventionally, motors have heavily been used in various types of equipment and devices. For example, driving motors for use in electric vehicles and hybrid vehicles, and motors for operations such as zooming and focusing inside lens barrels of video cameras and digital still cameras are significantly important for ensuring performance and required to output intended power with high accuracy relative to a control amount.

There has been a device (method) for inspecting such motors during attachment or manufacture of the motors. This device (method) includes an inverter, a motor control ECU, a torque meter, a load motor 5, a load motor control unit, an AC power measuring instrument, a DC power measuring instrument, a DC power supply, a motor output performance inspection controller, and a magnetic contractor for motor power cable connection, for example. This device (method) is configured in such a manner that the torque meter measures an output torque of an inspection target motor, the load motor generates a load torque on the inspection target motor, the AC power measuring instrument and the DC power measuring instrument measure power supplied to the inspection target motor, and the motor output performance inspection controller is responsible for control of operation of an entire system, measurement of inspection data, performance judgement, etc. (see patent document 1).

There has also been a motor inspection/control method (device) of applying voltages of difference frequencies to a magnetic coil, measuring an impedance at each frequency and acquiring a measured value about Z-F characteristics, comparing an allowable band of Z-F characteristics determined in advance on the basis of Z-F characteristics in a normal state of the magnetic coil with the measured value about the Z-F characteristics, and calculating a remaining time period of life from a standard deterioration start period and a standard deterioration progress period (see patent document 2).

According to another suggested method, an impedance curve is generated through a rotor impedance measurement test conducted during rotation of a generator, a sudden change line showing sudden change in the rotor impedance is searched for from the impedance curve by referring to a standard impedance curve generated in advance about a measurement subject generator or a generator of the same type during its normal operation, an auxiliary line interval is set for each of the sudden change lines, the standard impedance curve and the impedance curve are superimposed on each other, some parallel auxiliary lines are drawn at the auxiliary line interval below the standard impedance curve, and the number of auxiliary lines from an auxiliary line directly below the standard impedance curve to an auxiliary line passing the vicinity of the rotor impedance at an upper limited rotation number is determined as the number of coils where layer shorts have occurred (see patent document 3).

Patent Document 1: Japanese Unexamined Patent Application, Publication No. 2004-219354

Patent Document 2: Japanese Unexamined Patent Application, Publication No. 2016-24111

Patent Document 3: Japanese Unexamined Patent Application, Publication No. H11-326469

### SUMMARY OF THE INVENTION

In some cases, multiple terminals (power lines) such as three or six are provided at a three-phase motor. Connection error in such motor power lines (winding specification error in the motor) is directly associated with trouble such as reduction in motor output or overheating of the motor. Hence, inspection is required after attachment of the motor to check that there is no connection error in the motor power lines (winding specification error in the motor).

Meanwhile, all the inspection/control methods shown in patent document 1, patent document 2, and patent document 3 mentioned above are to determine the presence or absence of abnormality by measuring an actual voltage, etc. This inevitably necessitates use of a dedicated inspection device or measurement device. Additionally, applying these inspection/control methods to inspection for checking connection abnormality in the attached motor, for example, causes seriously poor usability and requires a great deal of time and effort.

In view of the foregoing circumstances, the present invention is intended to provide a motor controller and a motor control method allowing inspection for checking the presence or absence of specification error in motor winding to be conducted more simply, efficiently, and with high accuracy.

The present inventors have found that, by comparing the values of a voltage command value, a current value (actual current value), and an excitation frequency (command value) at the time of motor driving with theoretical values (design values, required values) of a voltage command value, a current value, and an excitation frequency respectively calculated from a parameter for driving the motor, it becomes possible to detect the presence or absence of abnormality in motor winding or in connection between the winding and a driving device, eventually, to detect specification error in the motor winding (connection error), thereby achieving the present invention.

(1) According to the present invention, a motor controller comprises: a current command calculation unit that calculates a current command for a current to flow in a motor; a current control unit that controls a motor current by changing a voltage command for a voltage to be applied to the motor; an actual current detection unit that detects an actual current flowing in the motor; a storage unit that stores a parameter for driving the motor; and a connection abnormality determination unit that compares a voltage command value, a current value, and an excitation frequency at the time of motor driving with theoretical values of a voltage command value, a current value, and an excitation frequency respectively calculated from the parameter, checks consistency between the characteristics of the driven motor and the parameter for driving the motor, and determines that there is abnormality in motor winding or in connection between the winding and a driving device if a result shows inconsistency therebetween.

(2) According to the preset invention, in the motor controller described in (1), at least one parameter for driving the motor may be an inductance value or a correlated value correlated with an inductance of the motor, and the connection abnormality determination unit may compare an actual inductance value of the driven motor obtained from the voltage command value, the current value, and the excitation frequency at the time of the motor driving or a correlated value correlated with an actual inductance with an inductance value calculated from the parameter or a correlated value correlated with an inductance, and check consistency therebetween.

(3) According to the present invention, a motor control method comprises: sampling a voltage command value as a command value for driving control of a motor and an excitation frequency; detecting an actual current flowing in the motor being driven under control; determining theoretical values of a voltage command value, a current, and an excitation frequency from a parameter for driving the motor and a condition at the time of driving; and comparing the theoretical values of the voltage command value, the current, and the excitation frequency with the values of the voltage command value, the current, and the excitation frequency respectively at the time of the driving, and determining that there is winding abnormality if differences between the comparable values exceed a threshold range set in advance.

(4) According to the present invention, in the motor control method described in (3), an inductance value or a correlated value correlated with an inductance may be used as the parameter. The method may comprise: sampling a voltage command value as a command value for driving control of the motor and an excitation frequency; detecting an actual current flowing in the motor being driven under control; determining an actual inductance value or a correlated value correlated with an actual inductance from the voltage command value, the actual current, and the excitation frequency; and comparing the inductance value as the parameter or the correlated value correlated with the inductance with the actual inductance value or the correlated value correlated with the actual inductance, and determining that there is winding abnormality if a difference between the comparable values exceeds a threshold range set in advance.

According to the inventions described in (1), (2), (3), and (4), the voltage command value, the current value, and the excitation frequency at the time of the motor driving are compared with the theoretical values of the voltage command value, the current value, and the excitation frequency respectively calculated from the parameter (such as an inductance value) for driving the motor. Then, consistencies, namely, differences between the comparable values are checked to determine the presence or absence of a difference exceeding allowable error set in advance. By doing so, specification error in motor winding (connection error) can be detected.

According to the present invention, compared to the conventional inspection conducted by actually measuring a voltage value, etc., failure or no-failure can be judged by determining the characteristics of a motor on the basis of a voltage command value output during control of a current in the motor. This makes it possible to inspect winding specifications of the motor more simply and efficiently.

### BRIEF DESCRIPTION OF THE DRAWINGS

FIG. 1 is a block diagram showing a motor controller according to an embodiment of the present invention;

FIG. 2 is a flow diagram showing a motor control method according to the embodiment of the present invention;

FIG. 3 shows an exemplary relationship between the rotation number, voltage, and inductance of a motor; and

FIG. 4 is a flow diagram showing a motor control method according to the embodiment of the present invention.

### DETAILED DESCRIPTION OF THE INVENTION

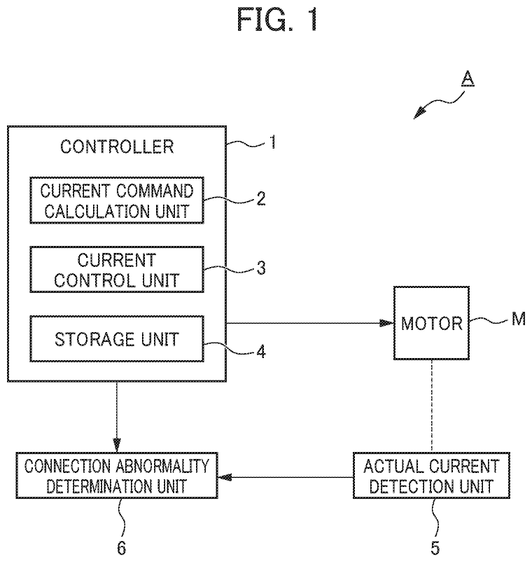

A motor controller and a motor control method according to an embodiment of the present invention will be described below by referring to FIGS. 1 to 4.

The embodiment relates to a motor controller and a motor control method allowing inspection for determining, for example, whether winding specification error (connection error) has occurred in an attached motor more simply and efficiently.

As shown in FIG. 1, a motor controller A (controller 1 of a motor inspection device A) of the embodiment includes a current command calculation unit 2 that calculates a current command for a current to flow in a motor, a current control unit 3 that controls a motor current by changing a voltage command value for a voltage to be applied to a motor M during driving control of the motor M, and a storage unit 4 that stores a parameter for driving the motor M.

The motor controller A of the embodiment further includes an actual current detection unit 5 that measures/detects an actual current flowing in the motor M, and a connection abnormality determination unit 6 that compares a voltage command value, a current value, and an excitation frequency at the time of motor driving with theoretical values (design values, required values) of a voltage command value, a current value, and an excitation frequency respectively calculated from a parameter, checks consistency between the characteristics of the driven motor and the parameter for driving the motor M, and determines that there is abnormality in motor winding or in connection between the winding and a driving device if a result shows inconsistency therebetween.

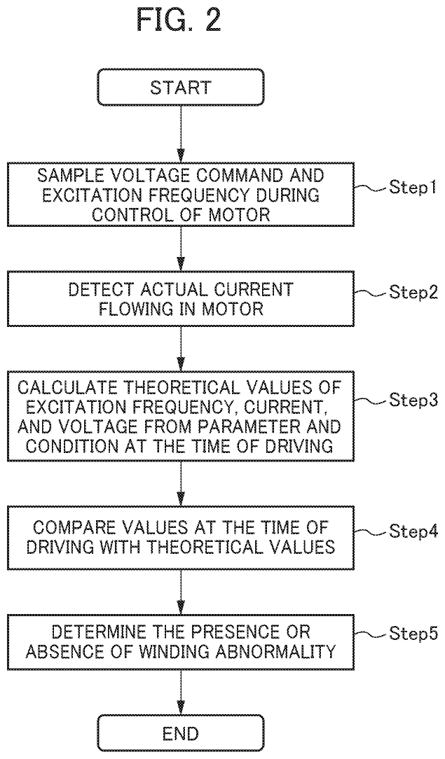

As shown in FIG. 2, for conducting inspection for checking winding specifications of an attached motor using the motor controller A of the embodiment having the foregoing configuration (according to the motor control method of the embodiment), a voltage command value as a command value for driving control of the motor and an excitation frequency are sampled (extracted) first (Step 1).

Next, an actual current flowing in the motor being driven under control is measured/detected (Step 2).

Then, theoretical values of a voltage, a current, and an excitation frequency are calculated from a parameter and a condition at the time of driving (such as a condition for a load on the motor) (Step 3).

Then, the theoretical values of the voltage, the current, and the excitation frequency are compared with the values of the voltage command value, the current, and the excitation frequency (command value) respectively at the time of driving (Step 4). If ranges of differences between the comparable values exceed a threshold range set in advance, in other words, if differences of the theoretical values of the voltage command value, the current, and the excitation frequency from the values of the voltage command value, the current, and the excitation frequency (command value) respectively at the time of the driving exceed an allowable error range, it is determined that there is winding abnormality in the motor. If the differences are within the threshold range, the winding is determined to be proper (Step 5). In this step, if a difference of any of the values from a corresponding theoretical value exceeds the allowable error, it is determined that there is winding abnormality.

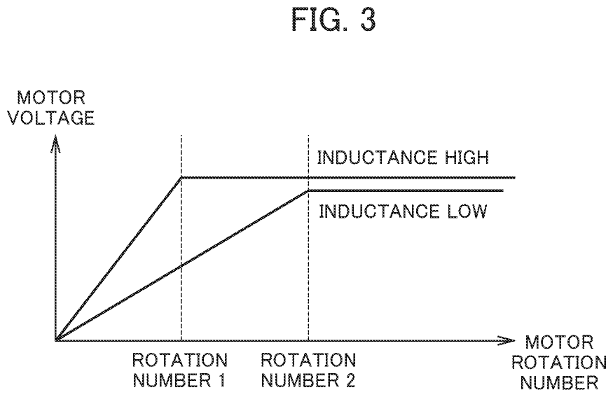

A voltage command value, an actual current, an excitation frequency, and an actual inductance value are related to each other expressed in FIG. 3 and by the following formula (1):

$$ACTUAL INDUCTANCE VALUE ∝ \frac{VOLTAGE COMMAND VALUE}{\begin{matrix}ACTUAL CURRENT \times \\ EXCITATION FREQUENCY\end{matrix}} \qquad [ Math . 1 ]$$

Thus, this actual inductance value is usable as the foregoing parameter. Further, an item correlated with an inductance can be handled as a parameter. If the motor is a synchronous motor, for example, a rotation number can be used as a parameter. Specifically, the motor according to the present invention can either be a synchronous motor or an induction motor.

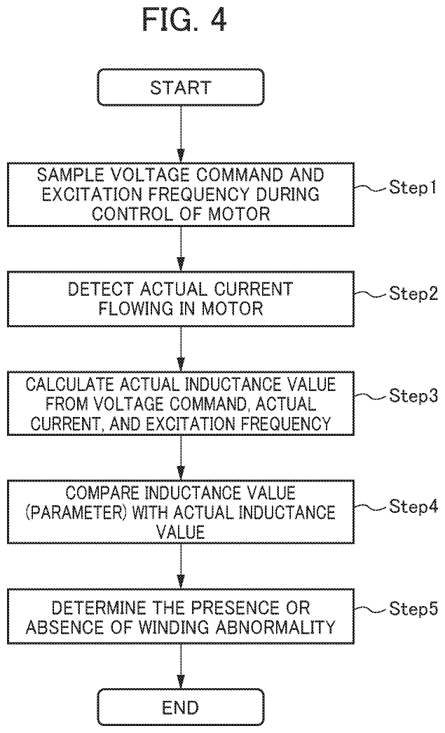

As shown in FIG. 4, if the actual inductance value is used, a voltage command value and an excitation frequency during control of the motor are sampled (Step 1). Then, an actual current flowing in the motor is measured/detected (Step 2).

Next, an actual inductance value is determined from the voltage command value, the actual current, and the excitation frequency and using FIG. 3 and the formula (1) (Step 3).

Then, an inductance value as a parameter and the actual inductance value are compared (Step 4). If a range of a difference therebetween exceeds a threshold range set in advance, it is determined that there is winding abnormality. If the difference is within the threshold range, the winding is determined to be proper (Step 5).

As described above, according to the motor controller A and the motor control method of the embodiment, a voltage command value, a current value, and an excitation frequency at the time of motor driving are compared with theoretical values of a voltage command value, a current value, and an excitation frequency respectively calculated from a parameter for driving a motor. Then, differences between the comparable values are checked to determine the presence or absence of a difference exceeding the allowable error set in advance, namely, to determine consistency. By doing so, specification error in motor winding (connection error) can be detected.

Thus, according to the motor controller A and the motor control method of the embodiment, compared to the conventional inspection conducted by actually measuring a voltage value, etc., failure or no-failure can be judged by determining the characteristics of a motor on the basis of a voltage command value output during control of a current in the motor. This makes it possible to inspect winding specifications of the motor more simply and efficiently.

As shown in FIG. 3, an inductance value changes with change in the rotation number of a motor or a voltage at the motor. Thus, by using this inductance value as a parameter and changing a voltage command value, winding specifications of the motor can be inspected easily under multiple conditions. This achieves implementation of inspection simply and efficiently even under multiple conditions. As a result, it becomes possible to conduct the inspection with high reliability and high accuracy.

While an embodiment of the motor controller and the motor control method according to the present invention has been described above, the present invention should not be limited to the foregoing embodiment but can be changed appropriately within a range not deviating from the substance of the invention.

### EXPLANATION OF REFERENCE NUMERALS

1 Controller
2 Current command calculation unit
3 Current control unit
4 Storage unit
5 Actual current detection unit
6 Connection abnormality determination unit
A Motor controller
M Motor

What is claimed is:

1. A motor controller comprising: a current command calculation unit that calculates a current command for a current to flow in a motor;
a current control unit that controls a motor current by changing a voltage command for a voltage to be applied to the motor;
an actual current detection unit that detects an actual current flowing in the motor;
a storage unit that stores a parameter for driving the motor; and
a connection abnormality determination unit that compares a voltage command value, a current value, and an excitation frequency at the time of motor driving with theoretical values of a voltage command value, a current value, and an excitation frequency respectively calculated from the parameter, checks consistency between the characteristics of the driven motor and the parameter for driving the motor, and determines that there is abnormality in motor winding or in connection between the winding and a driving device if a result shows inconsistency therebetween.

2. The motor controller according to claim 1, wherein
at least one parameter for driving the motor is an inductance value or a correlated value correlated with an inductance of the motor, and
the connection abnormality determination unit compares an actual inductance value of the driven motor obtained from the voltage command value, the current value, and the excitation frequency at the time of the motor driving or a correlated value correlated with an actual inductance with an inductance value calculated from the parameter or a correlated value correlated with an inductance, and checks consistency therebetween.

3. A motor control method comprising: sampling a voltage command value as a command value for driving control of a motor and an excitation frequency;
detecting an actual current flowing in the motor being driven under control;
determining theoretical values of a voltage command value, a current, and an excitation frequency from a parameter for driving the motor and a condition at the time of driving; and
comparing the theoretical values of the voltage command value, the current, and the excitation frequency with the values of the voltage command value, the actual current, and the excitation frequency respectively at the time of the driving, and determining that there is winding abnormality if differences between the comparable values exceed a threshold range set in advance.

4. The motor control method according to claim 3, wherein
an inductance value or a correlated value correlated with an inductance is used as the parameter, the method comprising:
sampling a voltage command value as a command value for driving control of the motor and an excitation frequency;
detecting an actual current flowing in the motor being driven under control;
determining an actual inductance value or a correlated value correlated with an actual inductance from the voltage command value, the actual current, and the excitation frequency; and
comparing the inductance value as the parameter or the correlated value correlated with the inductance with the actual inductance value or the correlated value correlated with the actual inductance, and determining that there is winding abnormality if a difference between the comparable values exceeds a threshold range set in advance.
